(19) United States
(12) Patent Application Publication
(10) Pub. No.: US 2019/0067008 A1
(43) Pub. Date: Feb. 28, 2019

(54) SEMICONDUCTOR STRUCTURES AND FABRICATION METHODS THEREOF

(71) Applicants: Semiconductor Manufacturing International (Shanghai) Corporation, Shanghai (CN); Semiconductor Manufacturing International (Beijing) Corporation, Beijing (CN)

(72) Inventors: Zhuo Fan CHEN, Shanghai (CN); Hai Yang ZHANG, Shanghai (CN)

(21) Appl. No.: 16/101,759

(22) Filed: Aug. 13, 2018

(30) Foreign Application Priority Data
Aug. 24, 2017 (CN) 201710734967.6

(51) Int. Cl. H01L 21/033; H01L 21/308; H01L 21/768; H01L 23/48; H01L 23/532

(52) U.S. Cl. CPC H01L 21/0337; H01L 21/3088; H01L 21/3086; H01L 23/53257; H01L 23/481; H01L 23/53233; H01L 21/76816

(57) ABSTRACT

A method for fabricating a semiconductor structure includes providing a base substrate; forming a first mask layer to cover a portion of the base substrate; forming a plurality of first sidewall spacers on sidewall surfaces of the first mask layer; and forming a second mask layer on the base substrate. The second mask layer covers the sidewall surfaces of the plurality of first sidewall spacers. The method also includes after forming the second mask layer, removing the plurality of first sidewall spacers; and after removing the plurality of first sidewall spacers, etching the base substrate using the first mask layer and the second mask layer as an etch mask to form a plurality of trenches in the base substrate.

### CROSS-REFERENCES TO RELATED APPLICATIONS

This application claims the priority of Chinese Patent Application No. CN201710734967.6, filed on Aug. 24, 2017, the entire content of which is incorporated herein by reference.

### FIELD OF THE DISCLOSURE

The present disclosure generally relates to the field of semiconductor fabrication technology and, more particularly, relates to semiconductor structures and fabrication methods thereof.

### BACKGROUND

In the field of semiconductor manufacturing, photoresist material is used to transfer a mask pattern into one or more layers of material. For example, using a photoresist material, a mask pattern may be transferred into a metal layer, a dielectric layer, or a semiconductor substrate. However, as the feature size of the semiconductor process is continuously reduced, it becomes more and more difficult to form a mask pattern with a small feature size in the material layer through a photolithography process.

In order to improve the integration level of semiconductor devices, various double patterning processes, including a self-aligned double patterning (SADP) process, have been used in the semiconductor industry.

With further improvement of the integration level of semiconductor devices, it became difficult for SADP process to meet the high integration requirements of semiconductor devices. In view of the problem, the industry has proposed an anti-spacer quadruple patterning (ASQP) process.

However, the dimensions of trenches formed by the existing ASQP process may become very different. The disclosed semiconductor structures and fabrication methods thereof are directed to solve one or more problems set forth above and other problems in the art.

### BRIEF SUMMARY OF THE DISCLOSURE

One aspect of the present disclosure provides a method for fabricating a semiconductor structure. The method includes providing a base substrate; forming a first mask layer to cover a portion of the base substrate; forming a plurality of first sidewall spacers on sidewall surfaces of the first mask layer; and forming a second mask layer on the base substrate. The second mask layer covers sidewall surfaces of the plurality of first sidewall spacers. The method also includes after forming the second mask layer, removing the plurality of first sidewall spacers; and after removing the plurality of first sidewall spacers, etching the base substrate using the first mask layer and the second mask layer as an etch mask to form a plurality of trenches in the base substrate.

Another aspect of the present disclosure provides a semiconductor structure. The semiconductor structure includes a base substrate; a first mask layer and a second mask layer formed on the base substrate and covering a portion of a top surface of the base substrate; and a plurality of first openings formed between sidewall surfaces of the first mask layer and the second mask layer. Each first opening is between a sidewall surface of the first mask layer and a sidewall surface of the second mask layer. The semiconductor structure also includes a plurality trenches formed in the base substrate. Each trench is formed under a first opening.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-4 illustrate schematic cross-section views of semiconductor structures at various stages in a quadruple patterning process;

FIGS. 5-17 illustrate schematic cross-section views of semiconductor structures at certain stages of an exemplary method for fabricating a semiconductor structure consistent with some embodiments of the present disclosure; and

FIG. 18 illustrates a flowchart of an exemplary method for fabricating a semiconductor device consistent with various embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

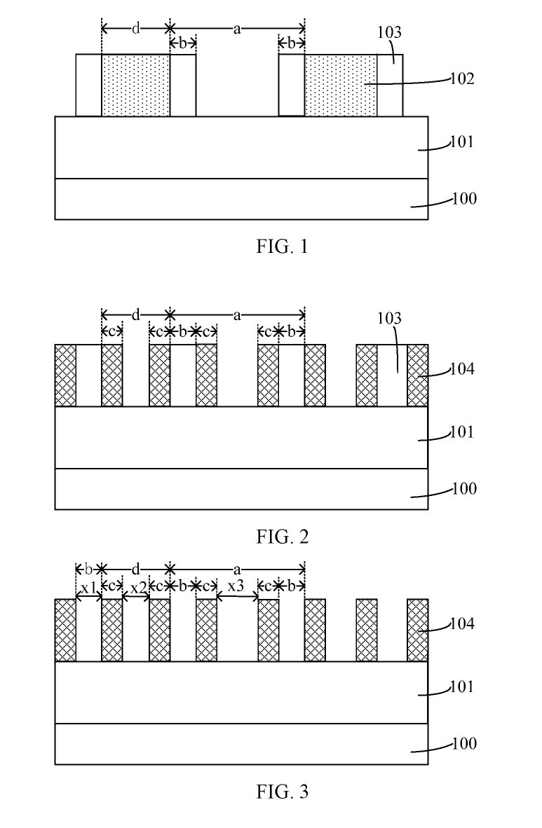

FIGS. 1-4 illustrate schematic cross-section views of semiconductor structures at various stages in a quadruple patterning process.

Referring to FIG. 1, a substrate 100 is provided. A dielectric layer 101 is formed on the substrate 100, and at least one sacrificial structure 102 is formed on the dielectric layer. A first sidewall spacer 103 is formed on each sidewall surface of the sacrificial structure 102.

Referring to FIG. 2, after forming the first sidewall spacers 103, the at least one sacrificial structure 102 (referring to FIG. 1) is removed. Further, after removing the at least one sacrificial structure 102, a second sidewall spacer 104 is formed on each sidewall surface of the first sidewall spacers 103.

Referring to FIG. 3, after forming the second sidewall spacers 104, the first sidewall spacers 103 are removed.

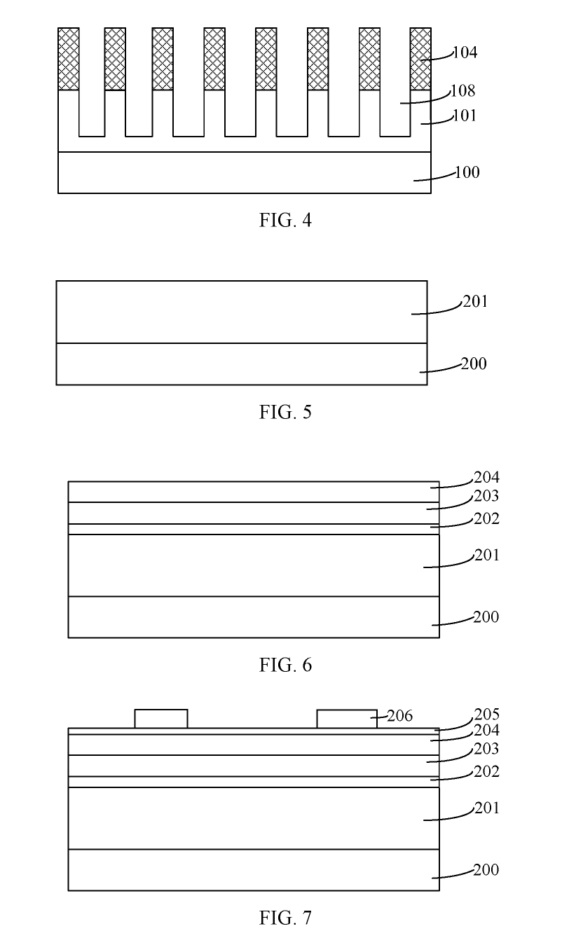

Referring to FIG. 4, after removing the first sidewall spacers 103, the dielectric layer 101 is etched using the second sidewall spacers 104 as an etch mask to form a plurality of trenches 108 in the dielectric layer 101.

However, the performance of the semiconductor structure formed by the method described above is undesired. The reasons are described in the following.

According to the method described above, the second sidewall spacers are used as the mask for forming the plurality of trenches 108. However, the distance between adjacent second sidewall spacers 104 may not be exactly the same. For example, the distance between adjacent second sidewall spacers 104 may include three spacing sizes, i.e., x1, x2, and x3 as shown in FIG. 3. Among the three spacing sizes, x1 may be equal to the thickness b of the first sidewall spacer 103, that is, x1 =b; x2 may be equal to the dimension d of the sacrificial structure 102 in a direction perpendicular to the sidewall surface of the second sidewall spacer 104 subtracted by 2 times of the thickness c of the second sidewall spacer 104, that is, x2=d−2c; and x3 may be equal to the distance a between adjacent sacrificial structures 102 subtracted by 2 times of the thickness b of the first sidewall spacer 103 and 2 times of the thickness c of the second sidewall spacer 104, that is, x3=a−2b−2c.

According to the expression of x1, the factors affecting the value of x1 may include the thickness of the first sidewall spacer 103; from the expression of x2, the factors affecting the value of x2 may include the dimension d of the sacrificial structure 102 in the direction perpendicular to the sidewall surface of the second sidewall spacer 104, and the thickness c of the second sidewall spacer 104; and from the expression of x3, the factors affecting the value of x3 may include the distance a between adjacent sacrificial structures 102, the thickness of the first sidewall spacer b, and the thickness c of the second sidewall spacer 104.

However, during the actual manufacturing process, it is difficult to ensure that the values of x1, x2, and x3 are exactly the same. Therefore, when using the plurality of second sidewall spacers 104 as the mask to etch the dielectric layer 101, it is difficult to ensure that the dimensions of the plurality of trenches 108 formed by etching the dielectric layer 101 are completely the same. In a subsequent process, the plurality of trenches 108 may be used to form interconnection structures. Therefore, when the dimensions of the plurality of trenches 108 are considerably different, the resistance and the capacitance of the interconnection structures formed in the plurality of trenches 108 may also be different, which may not be conducive to improving the performance of the semiconductor device.

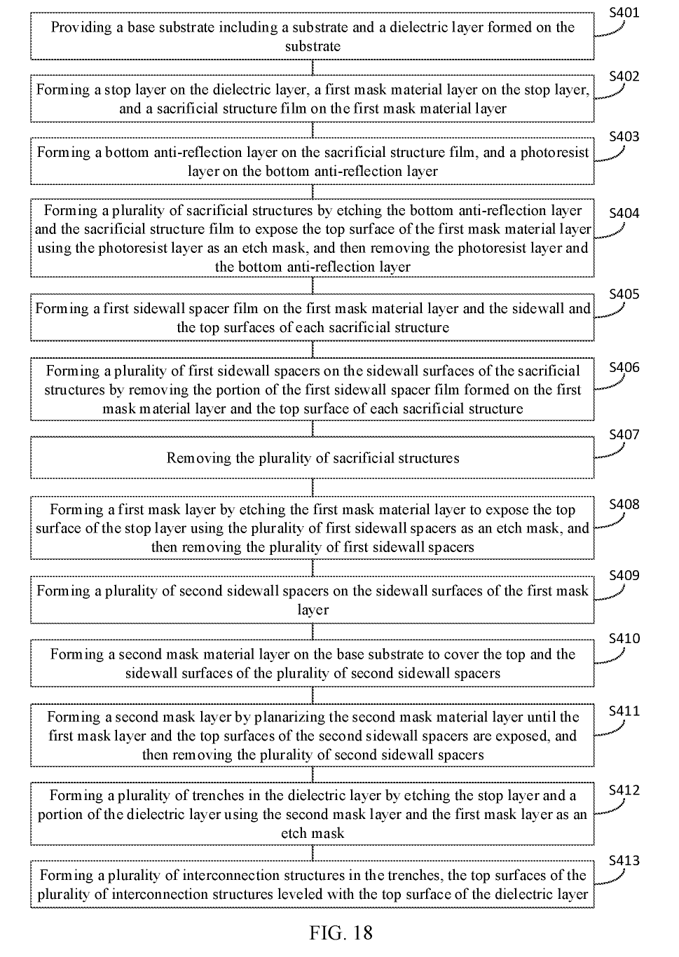

The present disclosure provides a method for fabricating semiconductor structures. FIG. 18 illustrates a flowchart of an exemplary method for fabricating a semiconductor device consistent with various embodiments of the present disclosure. FIGS. 5-17 illustrate schematic cross-section views of semiconductor structures at certain stages of the exemplary method.

Referring to FIG. 18, at the beginning of the fabrication process, a base substrate, including a substrate and a dielectric layer formed on the substrate, may be provided (S401). FIG. 5 illustrates a schematic cross-section view of a corresponding semiconductor structure consistent with various embodiments of the present disclosure.

Referring to FIG. 5, a base substrate may be provided. The base substrate may include a substrate 200 and a dielectric layer 201 formed on the substrate 200.

In one embodiment, the substrate 200 may be made of silicon. In other embodiments, the substrate may be made of germanium, SiGe, silicon on insulator (SOI), germanium on insulator (GOI), SiGe on insulator, or any other appropriate semiconductor material or semiconductor composite structure.

In other embodiments, a plurality of semiconductor devices, such as metal-oxide-semiconductor (MOS) transistors, may be formed in the substrate. In one embodiment, the dielectric layer 201 may have a single-layer structure. The dielectric layer 201 may be made of a material including a low-k dielectric material. The low-k dielectric material may refer to a material with a relative dielectric constant less than 3.9. The low-k dielectric material may be a porous material.

In one embodiment, the material for forming the dielectric layer 201 may include SiCOH. In other embodiments, the dielectric layer may have a single-layer structure, and the material for forming the dielectric layer may include fluorine-doped silicon dioxide (FSG), boron-doped silicon dioxide (BSG), phosphor-doped silicon dioxide (PSG), and/or boron-phosphor-doped silicon dioxide (BPSG). Alternatively, the dielectric layer may have a multiple-layer structure, and the dielectric layer may include a bottom stop layer formed on the top surface of the substrate 200 and a low-k dielectric layer formed on the bottom stop layer.

Further, returning to FIG. 18, a stop layer may be formed on the dielectric layer, a first mask material layer may be formed on the stop layer, and a sacrificial structure film may be formed on the first mask material layer (S402). FIG. 6 illustrates a schematic cross-section view of a corresponding semiconductor structure consistent with some embodiments of the present disclosure.

Referring to FIG. 6, a stop layer 202 may be formed on the dielectric layer 201, a first mask material layer 203 may be formed on the stop layer 202, and a sacrificial structure film 204 may be formed on the first mask material layer 203.

In one embodiment, the stop layer 202 may be made of SiOₓ. In other embodiments, the stop layer may be made of a material including SiNₓ, SiCN, SiCO, or any other appropriate material.

In one embodiment, the process for forming the stop layer 202 may include a high-density plasma chemical vapor deposition (CVD) process. The stop layer 202 may have the following functions. The stop layer 202 may be used to prevent the first mask material layer 203 and a subsequently-formed second mask material layer from entering the dielectric layer 201 such that the stop layer 202 may be conducive to improving the isolation properties of the dielectric layer 201. In addition, the stop layer 202 may also be used as a stop layer for removing a plurality of sidewall spacers in a subsequent process.

In one embodiment, the first mask material layer 203 may be made of a material including titanium oxide (TiOₓ). In other embodiments, the first mask material layer may be formed by a material including tungsten oxide (WOₓ) or zirconium oxide (ZrOₓ).

In one embodiment, the process for forming the first mask material layer 203 may include a spin coating process. The material for forming the first mask material layer 203 may be in a liquid state, and thus may be flowable. After solidifying the material to form the first mask material layer 203, the top surface of the first mask material layer 203 may be relatively flat, which may be conducive to the implementation of a subsequent planarization process.

In one embodiment, the first mask material layer 203 may be used to form a first mask layer.

In one embodiment, the sacrificial structure film 204 may be made of nitrogen-free carbon (NFC). In other embodiments, the sacrificial structure film may be an amorphous carbon layer (ACL), or may be made of amorphous silicon (a-Si), or any other appropriate material.

In one embodiment, the process for forming the sacrificial structure film 204 may include a fluid CVD process. The sacrificial structure film 204 may be used to form a plurality of sacrificial structures in a subsequent process.

Returning to FIG. 18, a bottom anti-reflection layer may be formed on the sacrificial structure film, and a photoresist layer may be formed on the top of the bottom anti-reflection layer (S403). FIG. 7 illustrates a schematic cross-section view of a corresponding semiconductor structure consistent with some embodiments of the present disclosure.

Referring to FIG. 7, a bottom anti-reflection layer 205 may be formed on the sacrificial structure film 204, and a photoresist layer 206 may be formed on the top of the bottom anti-reflection layer 205.

In one embodiment, the bottom anti-reflection layer 205 may have a multiple-layer structure. For example, the bottom anti-reflection layer 205 may include a first bottom anti-reflection layer (not shown) formed on the sacrificial structure film 204, and a second bottom anti-reflection layer (not shown) formed on the first bottom anti-reflection layer.

In one embodiment, the first bottom anti-reflection layer may be made of an inorganic material, such as SiON. When the first bottom anti-reflection layer is made of an inorganic material and the sacrificial structure film 204 is also made of an inorganic material, the first bottom anti-reflection layer and the sacrificial structure film 204 may have a desired interfacial state, which may be conducive to improving the performance of the semiconductor devices. The second bottom anti-reflection layer may be made of an organic material. When the second bottom anti-reflection layer is made of an organic material, and the photoresist layer 206 is also made of an organic material, the second bottom anti-reflection layer and the photoresist layer 206 may have a desired interfacial state, which may be conducive to improving the performance of the semiconductor devices.

In other embodiments, the bottom anti-reflection layer may have a single-layer structure. The bottom anti-reflection layer may be made of an organic material or an inorganic material.

In one embodiment, the bottom anti-reflection layer 205 may be used to reduce diffusive reflection and refraction of light during a subsequently-performed exposure process, and thus may be conducive to forming a plurality of sacrificial structures with desired morphology in a subsequent process.

The photoresist layer 206 may be used to subsequently pattern the sacrificial structure film 204.

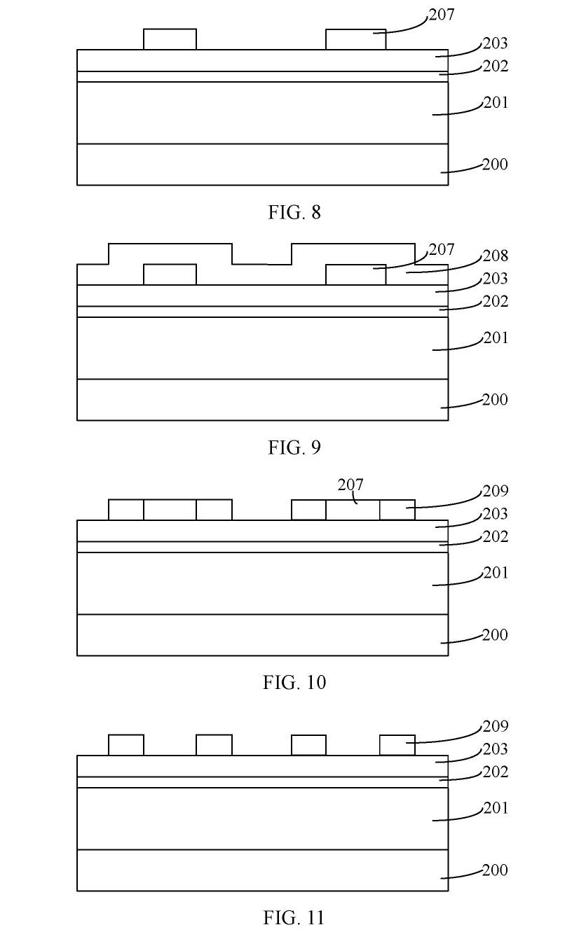

Further, returning to FIG. 18, using the photoresist layer as an etch mask, the bottom anti-reflection layer and the sacrificial structure film may be etched until the top surface of the first mask material layer is exposed such that a plurality of sacrificial structures may be formed, and after forming the plurality of sacrificial structures, the photoresist layer and the bottom anti-reflection layer may be removed (S404). FIG. 8 illustrates a schematic cross-section view of a corresponding semiconductor structure consistent with some embodiments of the present disclosure.

Referring to FIG. 8, the bottom anti-reflection layer 205 and the sacrificial structure film 204 may be etched using the photoresist layer 206 as an etch mask. As the top surface of the first mask material layer 203 is exposed, a plurality of sacrificial structures 207 may be formed. After forming the plurality of sacrificial structures 207, the photoresist layer 206 and the bottom anti-reflection layer 205 may be removed.

The process for etching the bottom anti-reflection layer 205 and the sacrificial structure film 204 using the photoresist layer 206 as the etch mask may include a dry etching process, a wet etching process, or an etching process combining dry etching and wet etching.

The process for removing the photoresist layer 206 and the bottom anti-reflection layer 205 may include an ashing process.

Further, returning to FIG. 18, after removing the photoresist layer and the bottom anti-reflection layer, a first sidewall spacer film may be formed on the first mask material layer and the sidewall and the top surfaces of each sacrificial structure (S405). FIG. 9 illustrates a schematic cross-section view of a corresponding semiconductor structure consistent with some embodiments of the present disclosure.

Referring to FIG. 9, after removing the photoresist layer 206 and the bottom anti-reflection layer 205, a first sidewall spacer film 208 may be formed on the first mask material layer 203 and the top and the sidewall surfaces of each sacrificial structure 207.

In one embodiment, the first sidewall spacer film 208 may be made of SiNₓ. In other embodiments, the first sidewall spacer film may be made of a material including SiOₓ or TiOₓ.

The process for forming the first sidewall spacer film 208 may include an atomic layer deposition (ALD) process. When the first sidewall spacer film 208 is formed by an ALD process, the thickness of the first sidewall spacer film 208 may be uniform. In a subsequent process, the first sidewall spacer film 208 may be used to form a plurality of first sidewall spacers.

Further, returning to FIG. 18, the portion of the first sidewall spacer film formed on the first mask material layer and the top surface of each sacrificial structure may be removed to form a plurality of first sidewall spacers on the sidewall surfaces of the sacrificial structures (S406). FIG. 10 illustrates a schematic cross-section view of a corresponding semiconductor structure consistent with some embodiments of the present disclosure.

Referring to FIG. 10, the portion of the first sidewall spacer film 208 formed on the first mask material layer 203 and the top surface of each sacrificial structure 207 may be removed to form a plurality of first sidewall spacers 209 on the sidewall surfaces of the sacrificial structures 207.

In one embodiment, the plurality of first sidewall spacers 209 may be made of SiNₓ. In other embodiments, the plurality of first sidewall spacers may be made of a material including SiOₓ or TiOₓ.

The process for removing the first mask material layer 203 and the portion of the first sidewall spacer film 208 formed on the top surface of each sacrificial structure 207 may include a dry etching process, a wet etching process, or a process combining dry etching and wet etching.

In one embodiment, exposing the top surfaces of the plurality of sacrificial layers 207 by removing the portion of the first sidewall spacer film 208 formed on the top surface of each sacrificial structure 207 may be conducive to the removal of the plurality of sacrificial structures in a subsequent process.

Further, returning to FIG. 18, after forming the plurality of first sidewall spacers, the plurality of sacrificial structures may be removed (S407). FIG. 11 illustrates a schematic cross-section view of a corresponding semiconductor structure consistent with some embodiments of the present disclosure.

Referring to FIG. 11, after forming a first sidewall spacer 209 on each sidewall surface of the plurality of sacrificial structures 207, the plurality of sacrificial structures 207 may be removed.

The process for removing the plurality of sacrificial structures 207 may include a dry etching process, a wet etching process, or a process combining dry etching and wet etching.

After removing the plurality of sacrificial structures 207, a portion of the top surface of the first mask material layer 203 may be exposed. Further, the first mask material layer 203 may be patterned using the plurality of first sidewall spacers 209 as a mask.

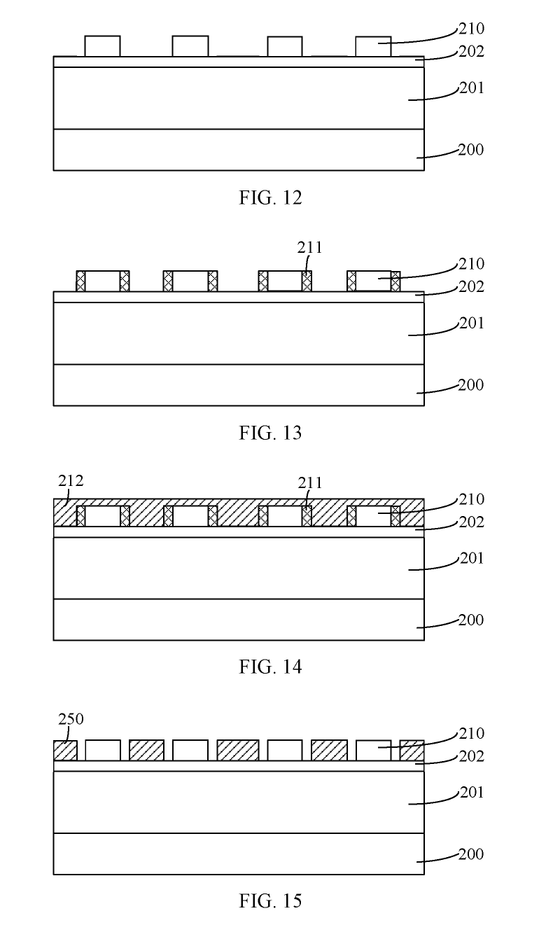

Returning to FIG. 18, further, a first mask layer may be formed by etching the first mask material layer using the plurality of first sidewall spacers as an etch mask until the top surface of the stop layer is exposed, and after forming the first mask layer, the plurality of first sidewall spacers may be removed (S408). FIG. 12 illustrates a schematic cross-section view of a corresponding semiconductor structure consistent with some embodiments of the present disclosure.

Referring to FIG. 12, the first mask material layer 203 may be etched using the plurality of first sidewall spacers 209 as an etch mask. As the top surface of the stop layer 202 is exposed, a first mask layer 210 may be formed. Further, the plurality of first sidewall spacers 209 may be removed.

The process for etching the first mask material layer 203 using the plurality of first sidewall spacers 209 as the etch mask may include a dry etching process, a wet etching process, or a process combining dry etching and wet etching.

The first mask layer 210 together with a subsequently-formed second mask layer may be used as a mask layer for forming a plurality of trenches in a subsequent process.

Returning to FIG. 18, further, a plurality of second sidewall spacers may be formed on the sidewall surfaces of the first mask layer (S409). FIG. 13 illustrates a schematic cross-section view of a corresponding semiconductor structure consistent with some embodiments of the present disclosure.

Referring to FIG. 13, a plurality of second sidewall spacers 211 may be formed on the sidewall surfaces of the first mask layer 210.

The process for forming the plurality of second sidewall spacers 211 may include the following exemplary steps. A second sidewall spacer film may be formed on the stop layer 202 and the top and the sidewall surfaces of the first mask layer 210. The portion of the second sidewall spacer film formed on the stop layer 202 and the top surface of the first mask layer 210 may be removed to form the plurality of second sidewall spacers 211.

In one embodiment, the second sidewall spacer film may be made of TiN, and accordingly, the plurality of second sidewall spacers 211 may also be made of TiN. In other embodiments, the second sidewall spacer film may be made of a material including TiO₂, and accordingly, the plurality of second sidewall spacers may also be made of a material including TiO₂.

The process for forming the second sidewall spacer film may include an ALD process. In one embodiment, the second sidewall spacer film may be made of TiN. Moreover, the second sidewall spacer film may be formed by an ALD process, and the parameters used in the ALD process may include a pressure in a range of 0 mTorr to approximately 100 mTorr, a power in a range of approximately 1000 watts to 10000 watts, a process gas including TiCl₄, NH₃, H₂, N₂, and Ar, a flow rate of TiCl₄ in a range of approximately 50 sccm to 100 sccm, a flow rate of NH₃ in a range of approximately 50 sccm to 500 sccm, a flow rate of H₂ in a range of approximately 20 sccm to 500 sccm, a flow rate of N₂ in a range of approximately 20 sccm to 500 sccm, and a flow rate of Ar in a range of approximately 100 sccm to 500 sccm.

When the second sidewall spacer film is formed by an ALD process, the thickness of the second sidewall spacer film may be uniform. In a subsequent process, the second sidewall spacer film may be used to form a plurality of second sidewall spacers 211. Therefore, the thickness of the plurality of second sidewall spacers 211 may be uniform. After removing the plurality of second sidewall spacers 211, the dielectric layer 201 may be etched in a subsequent process using the first mask layer 210 and the subsequently-formed second mask layer as an etch mask to form the plurality of trenches. Because the thickness of the plurality of second sidewall spacers 211 are uniform, the dimensions of the plurality of trenches may be the same. Therefore, the variation in the dimensions of the interconnection structures that are subsequently formed in the plurality of trenches may be limited, which may be conducive to improving the performance of the interconnection structures.

The process for removing the second sidewall spacer film formed on the stop layer 202 and the top surface of the first mask layer 210 may include a dry etching process, a wet etching process, or a process combining dry etching and wet etching.

The second sidewall spacer 211 and the first mask layer 210 may be made of different materials such that when removing the second sidewall spacer 211 in a subsequent process, damage to the sidewalls of the first mask layer 210 may be limited. As the morphology of the sidewalls of the first mask layer 210 is desired, in a subsequent process, by etching the dielectric layer 201 using the first mask layer 210 and the subsequently-formed second mask layer as the etch mask in a subsequent process, the variation in the dimensions of the trenches formed in the dielectric layer 201 may be limited. Further, when a plurality of interconnection structures (for example, a plurality of interconnection wires) are formed in the plurality of trenches in a subsequent process, the variation of the dimensions of the formed interconnection structures may be limited, which may be conducive to improve the performance of the interconnection structures.

The plurality of second sidewall spacers 211 may define the positions and the dimensions of a plurality of trenches formed in a subsequent process.

The thickness of the plurality of second sidewall spacers 211 may not be too small or too large. When the thickness of the second sidewall spacers 211 is too small, for example, smaller than 8 nm, the dimension of the plurality of subsequently-formed trenches in a direction parallel to the surface of the substrate 200 may be too small such that subsequent formation of the interconnection structures in the trenches may be difficult. When the thickness of the second sidewall spacers 211 is too large, for example, larger than 16 nm, the dimension of the plurality of subsequently-formed trenches in a direction parallel to the surface of the substrate 200 may be too large, and thus may not be conducive to improving the integration level of the semiconductor devices. Therefore, in one embodiment, the thickness of the plurality of second sidewall spacers 211 may be in a range of approximately 8 nm to 16 nm.

Further, returning to FIG. 18, a second mask material layer may be formed on the base substrate, and the second mask material layer may cover the top and the sidewall surfaces of the plurality of second sidewall spacers (S410). FIG. 14 illustrates a schematic cross-section view of a corresponding semiconductor structure consistent with some embodiments of the present disclosure.

Referring to FIG. 14, a second mask material layer 212 may be formed on the base substrate, and the second mask material layer 212 may cover the top and the sidewall surfaces of each second sidewall spacer 211.

In one embodiment, the second mask material layer 212 may be made of a material the same as the material for forming the first mask layer 210. For example, the second mask material layer 212 and the first mask layer 210 may both be made of TiOₓ. In other embodiments, the second mask material layer may be made of a material including ZrOₓ or WOₓ.

In one embodiment, the process for forming the second mask material layer 212 may include a spin coating process.

The material for forming the second mask material layer 212 may be in a liquid state, and thus may be flowable. After solidifying the material to form the second mask material layer 212, the top surface of the second mask material layer 212 may be relatively flat, which may help the implementation of a subsequent planarization process.

In one embodiment, the second mask material layer 212 may be used to form a second mask layer.

Further, returning to FIG. 18, a second mask layer may be formed by performing a planarization process on the second mask material layer until the first mask layer and the top surfaces of the plurality of second sidewall spacers are exposed, and after performing the planarization process, the plurality of second sidewall spacers may be removed (S411). FIG. 15 illustrates a schematic cross-section view of a corresponding semiconductor structure consistent to with some embodiments of the present disclosure.

Referring to FIG. 15, a second mask layer 250 may be formed by performing a planarization process on the second mask material layer 212 until the first mask layer 210 and the top surfaces of the plurality of second sidewall spacers 211 are exposed. After performing the planarization process, the plurality of second sidewall spacers 211 may be removed.

Performing the planarization process on the second mask material layer 212 may include a chemical mechanic polishing (CMP) process. The second mask material layer 212 may be planarized to expose the top surfaces of the plurality of second sidewall spacers 211, which may be conducive to the removal of the plurality of second sidewall spacers 211 in a subsequent process.

The process for removing the plurality of second sidewall spacers 211 may include a dry etching process, a wet etching process, or a process combining dry etching and wet etching.

In one embodiment, the plurality of second sidewall spacers 211 may be made of TiN, and the process for removing the plurality of second sidewall spacers 211 may include an anisotropic dry etching process. The parameters adopted in the anisotropic dry etching process may include a pressure in a range of approximately 5 mTorr to 100 mTorr, an inductively-coupled plasma power in a range of approximately 400 watts to 1200 watts, an offset voltage in a range of approximately 10 V to 100 V, an etching gas including Cl₂ and He, a flow rate of Cl₂ in a range of approximately 20 sscm to 200 sscm, a flow rate of He in a range of approximately 50 sscm to 400 sscm, and a temperature in a range of approximately 40° C. to 60° C.

In one embodiment, the second mask layer and the plurality of second sidewall spacers 211 may be made of different materials, and a selective etching ratio of the second mask layer 250 and the second sidewall spacers 211 may be in a range of approximately 10:1 to 20:1. As such, when removing the plurality of second sidewall spacers 211 in a subsequent process, damage to the sidewall surfaces of the second mask layer 250 may be limited, and thus the sidewalls of the second mask layer 250 may have desired morphology. Accordingly, the first mask layer 210 and the plurality of second sidewall spacers 211 may also be made of different materials, and a selective etching ratio of the first mask layer and the plurality of second sidewall spacers 211 may be in a range of approximately 10:1 to 20:1. As such, when removing the plurality of second sidewall spacers 211 in a subsequent process, damage to the sidewall surfaces of the first mask layer 210 may be limited, and thus the sidewalls of the first mask layer 210 may have desired morphology. Moreover, the dimensions of the plurality of second sidewall spacers 211 in the direction perpendicular to the sidewall surface of the first mask layer 210 may be uniform, such that when removing the plurality of second sidewall spacers 211, the openings formed between the first mask layer 210 and the second mask layer 250 may have a uniform dimension in a direction perpendicular to the sidewall surfaces of the first mask layer 210. Therefore, when etching the dielectric layer 201 using the first mask layer 210 and the second mask layer 250 as an etch mask in a subsequent process, the variation in the dimensions of the trenches formed on the dielectric layer 201 may be limited. Further, when a plurality of interconnection structures are formed in the plurality of trenches in a subsequent process, the variation in the dimensions of the formed interconnection structures may be limited, which may be conducive to improve the performance of the interconnection structures.

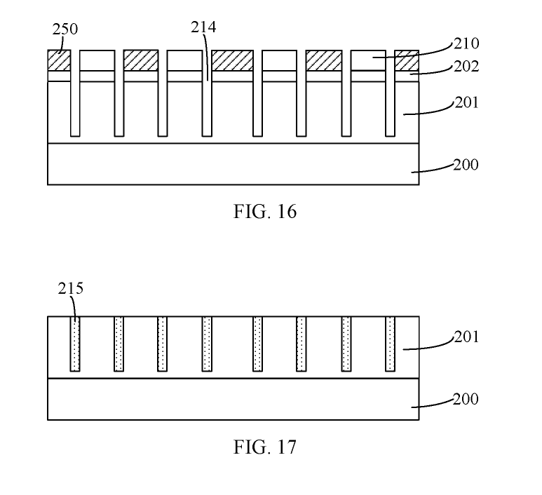

Further, returning to FIG. 18, a plurality of trenches may be formed in the dielectric layer by etching the stop layer and a portion of the dielectric layer using the second mask layer and the first mask layer as an etch mask (S412). FIG. 16 illustrates a schematic cross-section view of a corresponding semiconductor structure consistent with some embodiments of the present disclosure.

Referring to FIG. 16, a plurality of trenches 214 may be formed in the dielectric layer 201 by etching the stop layer 202 and a portion of the dielectric layer 201 using the second mask layer 250 and the first mask layer 210 as an etch mask.

The process for etching the stop layer 102 and a portion of the dielectric layer 201 using the second mask layer 250 and the first mask layer 210 as the etch mask may include a dry etching process, a wet etching process, or a process combining dry etching and wet etching.

During the process for forming the plurality of trenches 214, because the variation in the dimensions of the openings formed between the second mask layer 250 and the first mask layer 210 in the direction parallel to the surface of the substrate 200 is limited, by using the second mask layer 250 and the first mask layer 210 as the etch mask, the formed plurality of trenches 214 may have a uniform dimension. Further, when a plurality of interconnection structures are formed in the plurality of trenches 214, the variation in the dimensions of the interconnection structures may also be limited, which may be conducive to improving the performance of the interconnection structures.

In one embodiment, in the direction parallel to the surface of the substrate 200, the dimensions of the trenches 214 may be in a range of approximately 8 nm to 16 nm.

Further, returning to FIG. 18, a plurality of interconnection structures may be formed in trenches, and the top surfaces of the plurality of interconnection structures may be exposed by the top surface of the dielectric layer (S413). FIG. 17 illustrates a schematic cross-section view of a corresponding semiconductor structure consistent with some embodiments of the present disclosure.

Referring to FIG. 17, a plurality of interconnection structures 215 may be formed in the plurality of trenches 214 (referring to FIG. 16). The top surfaces of the plurality of interconnection structures 215 may be leveled with the top surface of the dielectric layer 201.

The process for forming the plurality of interconnection structures 215 may include the following exemplary steps. A metal layer may be formed on the substrate 200, the first mask layer 210, and the second mask layer 250. The metal layer may also fill up the plurality of trenches 214. The metal layer may then be planarized until the top surface of the dielectric layer 201 is exposed. As such the plurality of interconnection structures 215 may be formed.

The metal layer may be made of a metal. In one embodiment, the metal layer may be made of Cu, and accordingly, the plurality of interconnection structures 215 may also be made of Cu. In other embodiments, the metal layer may be made of a material including Al, and accordingly, the plurality of interconnection structures 215 may also be made of the material including Al.

The process for planarizing the metal layer may include a CMP process.

During the planarization process, the stop layer 202, the first mask layer 210, and the second mask layer 250 formed on the dielectric layer 201 may all be removed.

Because the variation in the dimensions of the trenches 214 (referring to FIG. 16) is limited, the variation in the dimensions of the interconnection structures 215 formed in the trenches 214 may also be limited, which may be conducive to improving the performance of the interconnection structures 215.

The present disclosure also provides a semiconductor structure fabricated by the method described above. FIG. 16 illustrates a schematic cross-section view of an exemplary semiconductor structure consistent with some embodiments of the present disclosure.

Referring to FIG. 16, the semiconductor structure may include a base substrate, a first mask layer 210, and a second mask layer 250. The first mask layer 210 and the second mask layer 250 may cover a portion of the base substrate. A plurality of first openings may be formed between the sidewalls of the first mask layer 210 and the second mask layer 250. Each first opening may be formed between a sidewall of the first mask layer 210 and an adjacent sidewall of the second mask layer 250. The semiconductor structure may also include a plurality of trenches 214 formed in the base substrate under the plurality of first openings.

In one embodiment, the base substrate may include a substrate 200 and a dielectric layer 201 formed on the substrate 200. The first mask layer 210 and the second mask layer 250 may be formed to cover a portion of the dielectric layer 201. The plurality of trenches 214 may be formed in the dielectric layer 201 and connected to the plurality of first openings between the sidewalls of the first mask layer 210 and the second mask layer 250.

In a direction perpendicular to the sidewall surfaces of the first mask layer 210, the dimension of the first openings may be in a range of approximately 8 nm to 16 nm.

The first mask layer 210 and the second mask layer 250 may be made of a same material. In one embodiment, the first mask layer 210 and the second mask layer 250 may both be made of TiOₓ, WOₓ, or ZrOₓ.

In a direction parallel to the surface of the substrate 200, the dimension of the plurality of trenches 214 may be in a range of approximately 8 nm to 16 nm.

Further, the semiconductor structure may also include a plurality of interconnection structures (not shown) formed in the plurality of trenches 214. For example, the plurality of interconnection structures may be interconnection wires.

Compared to conventional semiconductor structures and fabrication methods, the disclosed semiconductor structures and fabrication methods may demonstrate the following advantages.

According to the disclosed semiconductor structures and fabrication methods, a plurality of second sidewall spacers are formed on the sidewalls of a first mask layer, and after forming the plurality of second sidewall spacers, a second mask layer is formed on the base substrate. The second mask layer covers the sidewall surfaces of the plurality of second sidewall spacers. That is, each second sidewall spacer may be located between the first mask layer and the second mask layer. The dimensions of the plurality of second sidewall spacers are uniform along a direction perpendicular to the sidewall surfaces of the first mask layer. After removing the plurality of second sidewall spacers in a subsequent process, the base substrate is etched by using the first mask layer and the second mask layer as an etch mask to form a plurality of trenches. Because the dimensions of the plurality of second sidewall spacers are uniform along the direction perpendicular to the sidewall surfaces of the first mask layer, the variation in the dimensions of the trenches formed in the base substrate is limited. Further, after a plurality of interconnection structures are formed in the plurality of trenches in a subsequent process, the variation in the dimensions of the interconnection structures is also limited, which may be conducive to improving the performance of the semiconductor structures.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A method for fabricating a semiconductor structure, comprising:
providing a base substrate;
forming a first mask layer to cover a portion of the base substrate;
forming a plurality of first sidewall spacers on sidewall surfaces of the first mask layer;
forming a second mask layer on the base substrate, wherein the second mask layer covers sidewall surfaces of the plurality of first sidewall spacers;
after forming the second mask layer, removing the plurality of first sidewall spacers; and
after removing the plurality of first sidewall spacers, etching the base substrate using the first mask layer and the second mask layer as an etch mask to form a plurality of trenches in the base substrate.

2. The method according to claim 1, wherein forming the first mask layer includes:
forming a first mask material layer on the base substrate;
forming at least one sacrificial structure to cover a portion of the first mask material layer;
forming a plurality of second sidewall spacers on sidewall surfaces of the at least one sacrificial structure;
after forming the plurality of second sidewall spacers, removing the at least one sacrificial structure; and
after removing the at least one sacrificial structure, forming the first mask layer by etching the first mask material layer to expose a top surface of the base substrate using the plurality of second sidewalls as an etch mask.

3. The method according to claim 2, wherein:
the at least one sacrificial structure is made of a material including nitrogen-free carbon, amorphous carbon, or amorphous silicon.

4. The method according to claim 1, wherein:
a dimension of each first sidewall spacer in a direction perpendicular to the sidewall surfaces of the first mask layer is in a range of approximately 8 nm to 16 nm.

5. The method according to claim 1, wherein:
the plurality of first sidewall spacers are made of a material including TiN or TiO₂.

6. The method according to claim 5, wherein the plurality of first sidewall spacers are made of TiN, and:
forming the plurality of first sidewall spacers includes an atomic layer deposition (ALD) process, wherein process parameters used in the ALD process include:
a pressure in a range of 0 mTorr to approximately 100 mTorr;
a power in a range of approximately 1000 watts to 10000 watts;
a process gas including TiCl₄, NH₃, H₂, N₂, and Ar;
a flow rate of TiCl₄ in a range of approximately 50 sccm to 100 sccm;
a flow rate of NH₃ in a range of approximately 50 sccm to 500 sccm;
a flow rate of H₂ in a range of approximately 20 sccm to 500 sccm;
a flow rate of N₂ in a range of approximately 20 sccm to 500 sccm; and
a flow rate of Ar in a range of approximately 100 sccm to 500 sccm.

7. The method according to claim 1, wherein:
the first mask layer and the second mask layer are made of a same material, including TiOₓ, WOₓ, or ZrOₓ.

8. The method according to claim 1, wherein the plurality of first sidewall spacers are made of TiN, and:
removing the plurality of first sidewall spacers includes an anisotropic dry etching process, wherein process parameters used in the anisotropic dry etching process include:
a pressure in a range of approximately 5 mTorr to 100 mTorr;
an inductively-coupled plasma power in a range of approximately 400 watts to 1200 watts;
an offset voltage in a range of approximately 10 V to 100 V;
an etching gas including Cl₂ and He;
a flow rate of Cl₂ in a range of approximately 20 sscm to 200 sscm;
a flow rate of He in a range of approximately 50 sscm to 400 sscm; and
a temperature in a range of approximately 40° C. to 60° C.

9. The method according to claim 1, wherein:
a selective etching ratio of the plurality of first sidewall spacers and the first mask layer is in a range of approximately 10:1 to 20:1; and
a selective etching ratio of the plurality of first sidewall spacers and the second mask layer is in a range of approximately 10:1 to 20:1.

10. The method according to claim 1, wherein:
in a direction perpendicular to the sidewall surfaces of the first mask layer, a dimension of the plurality of trenches is in a range of approximately 8 nm to 16 nm.

11. The method according to claim 1, after forming the plurality of trenches, further including:
forming a plurality of interconnection structures in the plurality of trenches, wherein:
the plurality of interconnection structures are made of a metal including Cu or Al.

12. The method according to claim 1, wherein:
the base substrate includes a substrate and a dielectric layer formed on the substrate; and
the plurality of trenches are formed in the dielectric layer.

13. The method according to claim 2, wherein:
prior to forming the first mask material layer, a stop layer is formed on the base substrate; and
the first mask material layer is formed on the stop layer.

14. The method according to claim 2, wherein forming the at least one sacrificial structure to cover the portion of the first mask material layer includes:
forming a sacrificial structure film on the first mask material layer;
forming a bottom anti-reflection layer on the sacrificial structure film;
forming a photoresist layer on the bottom anti-reflection layer, wherein the photoresist layer exposes a portion of a top surface of the bottom anti-reflection layer;
forming the at least one sacrificial structure by etching the bottom anti-reflection layer and the sacrificial structure film to expose a top surface of the first mask material layer using the photoresist layer as an etch mask.

15. A semiconductor structure, comprising:
a base substrate;
a first mask layer and a second mask layer formed on the base substrate and covering a portion of a top surface of the base substrate,
a plurality of first openings formed between sidewall surfaces of the first mask layer and the second mask layer, wherein each first opening is between a sidewall surface of the first mask layer and a sidewall surface of the second mask layer; and
a plurality trenches formed in the base substrate, wherein each trench is formed under a first opening.

16. The semiconductor structure according to claim 15, wherein:
a dimension of each first trench in a direction perpendicular to the sidewall surfaces of the first mask layer is in a range of approximately 8 nm to 16 nm.

17. The semiconductor structure according to claim 15, wherein:
the first mask layer and the second mask layer are made of a same material, including TiOₓ, WOₓ, or ZrOₓ.

18. The semiconductor structure according to claim 15, wherein:
in a direction perpendicular to the sidewall surfaces of the first mask layer, a dimension of the plurality of trenches is in a range of approximately 8 nm to 16 nm.

19. The semiconductor structure according to claim 15, further including:
a plurality of interconnection structures formed in the plurality of trenches.

20. The semiconductor structure according to claim 15, wherein:
the base substrate includes a substrate and a dielectric layer formed on the substrate; and
the plurality of trenches are formed in the dielectric layer.
